(19) United States
(12) Patent Application Publication
(10) Pub. No.: US 2006/0049490 A1
(43) Pub. Date: Mar. 9, 2006

(54) Displaying apparatus

(76) Inventor: Sang-bum Byun, Suwon-si (KR)

Correspondence Address: STANZIONE & KIM, LLP, 919 18TH STREET, N.W., SUITE 440, WASHINGTON, DC, 20006, US

(21) Appl. No.: 11/216,128

(22) Filed: Sep. 1, 2005

(30) Foreign Application Priority Data
Sep. 3, 2004 (KR) 2004-70438

(51) Int. Cl. H01L 23/552

(52) U.S. Cl. 257/659

(57) ABSTRACT

A displaying apparatus includes a printed circuit board (PCB), an integrated circuit (IC) provided on the PCB, a shield case enclosing the PCB, an electromagnetic wave conducting part interposed between and in contact with the IC and the shield case to conduct electromagnetic waves generated from the IC into the shield case, and a grounding part to be in contact with the shield case to by-pass the electromagnetic waves conducted into the shield case through the electromagnetic wave conducting part. Thus the displaying apparatus is capable of shielding electromagnetic waves generated from the IC mounted on the PCB simply and efficiently.

### CROSS-REFERENCE TO RELATED APPLICATIONS

This application claims the benefit under 35 U.S.C § 119 of Korean Patent Application No. 2004-70438, filed on Sep. 3, 2004, in the Korean Intellectual Property Office, the disclosure of which is incorporated herein in its entirety and by reference.

### BACKGROUND OF THE INVENTION

1. Field of the Invention

The present general inventive concept relates to a displaying apparatus, and more particularly, to a displaying apparatus having an improved electromagnetic wave shielding structure.

2. Description of the Related Art

The term “displaying apparatus” used in this description collectively refers to various kinds of apparatuses each visually displaying data on a face of a display panel in the form of text or picture.

As a variety of circuit components used in a displaying apparatus have each needed a high capacity and a high integration, a phenomenon of electromagnetic interference (EMI) has been generated. The EMI causes electromagnetic waves generated by a radiated emission (RE) or a conducted emission (CE) to interfere with functions of other devices, thereby deteriorating functions of the circuit and causing malfunctions of the devices.

As illustrated in FIG. 1, a conventional displaying apparatus comprises a printed circuit board (PCB) 2, an integrated circuit (IC) 4 provided on the PCB 2, a shield case 6 enclosing the PCB 2, and a grounding part 8 that is in contact with the shield case 6 for removing electromagnetic waves. The shield case 6 conducts the electromagnetic waves generated from a variety of circuit components mounted on the PCB 2 into the grounding part 8.

However, when excessive electromagnetic waves are emitted from the integrated circuit 4, the conventional displaying apparatus cannot completely shield the electromagnetic waves with only the shield case 6, and a phenomenon of EMI occurs.

Recently, a connector and an assembly for mounting an IC having a structure connected to the IC, capable of shielding heat generation and electromagnetic waves, to minimize the phenomenon of the EMI from the IC has been disclosed in Japanese First Publication No. 2004-6299. However, they are disadvantageous in that the electromagnetic wave shielding structure is complicated, thereby deteriorating an assembling efficiency and incurring a large production cost.

### SUMMARY OF THE INVENTION

The present general inventive concept provides a displaying apparatus capable of shielding electromagnetic waves generated from an IC mounted on a PCB simply and efficiently.

Additional aspects and advantages of the present general inventive concept will be set forth in part in the description which follows and, in part, will be obvious from the description, or may be learned by practice of the general inventive concept.

The foregoing and/or other aspects and advantages of the present general inventive concept may be achieved by providing a displaying apparatus, comprising a printed circuit board (PCB), an integrated circuit (IC) provided on the PCB, a shield case enclosing the PCB, an electromagnetic wave conducting part interposed between and in contact with the IC and the shield case to conduct electromagnetic waves generated from the IC into the shield case, and a grounding part to be in contact with the shield case to remove the electromagnetic waves conducted into the shield case through the electromagnetic wave conducting part.

The electromagnetic wave conducting part may comprise a pair of conductive contact parts to be in contact with the IC and the shield case, respectively, and an elastic part interposed between the pair of conductive contact parts to elastically keep the pair of conductive contact parts in contact with the IC and the shield case, respectively.

Each of the pair of conductive contact parts may comprise a conductive fabric.

The electromagnetic wave conducting part may be projecting inward from the shield case.

The electromagnetic wave conducting part may be integrally formed with the shield case.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a sectional view illustrating an electromagnetic wave shielding structure of a conventional displaying apparatus;

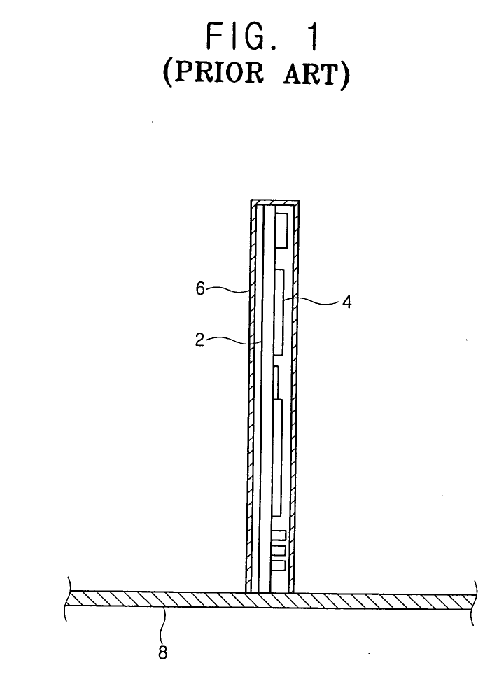

FIG. 2 is a perspective view illustrating an electromagnetic wave shielding structure of a displaying apparatus according to an embodiment of the present general inventive concept;

FIG. 3 is a sectional view illustrating the electromagnetic wave shielding structure of FIG. 2;

FIG. 4 is a sectional view illustrating an electromagnetic wave conducting part of the electromagnetic wave shielding structure of FIG. 3; and

FIG. 5 is a sectional view illustrating an electromagnetic wave shielding structure of a displaying apparatus according to another embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

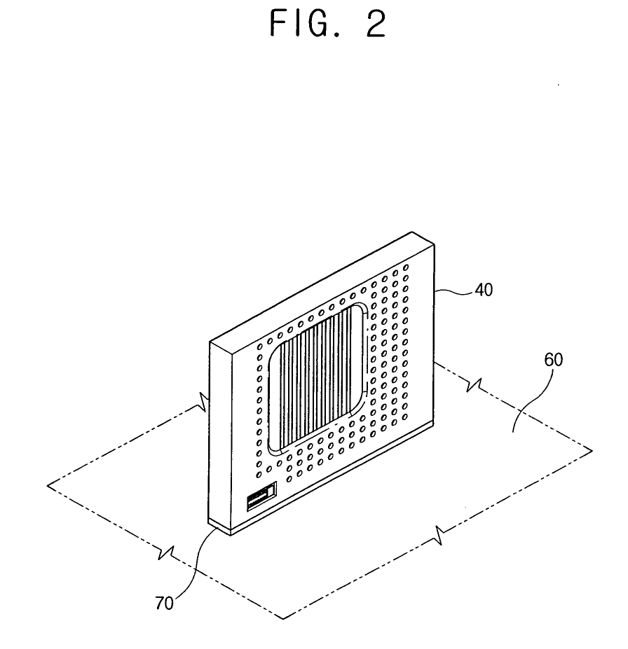

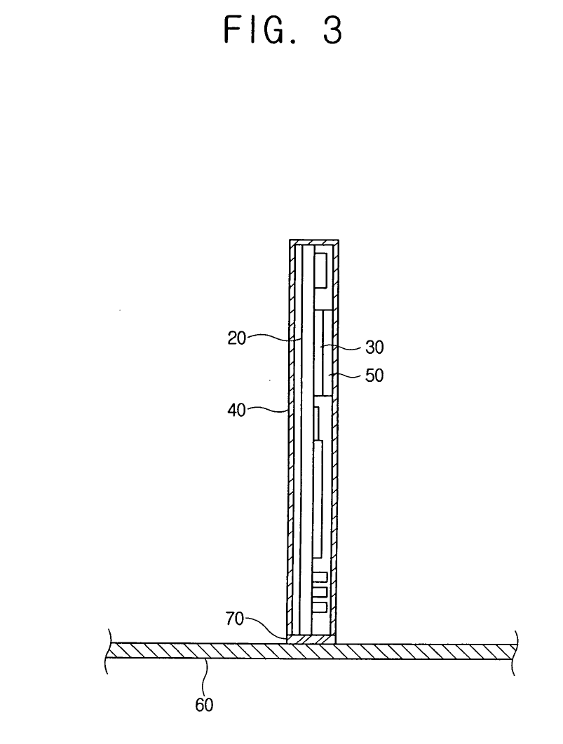

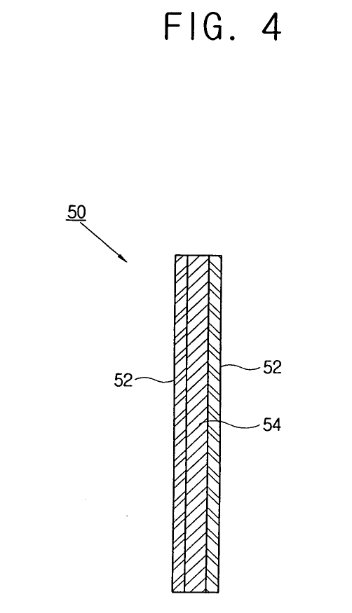

Referring to FIGS. 2 to 4, a displaying apparatus according to an embodiment of the present general inventive concept comprises a printed circuit board (PCB) 20, an integrated circuit (IC) 30 provided on the PCB, a shield case 40 enclosing the PCB, an electromagnetic wave conducting part 50 interposed between and in contact with the PCB 30 and the shield case 40, to conduct electromagnetic waves generated from the IC 30 into the shield case 40, and a grounding part 60 to by-pass the electromagnetic waves conducted into the shield case 40 through the electromagnetic wave conducting part 50.

A variety of circuit components including the IC 30 can be disposed on the PCB 20.

The IC 30 has a high capacity and a high integration, and can generate excessive electromagnetic waves. When the electromagnetic waves generated from the IC 30 are not properly shielded, significant damages to the circuit components may be caused due to electromagnetic interference (EMI).

The shield case 40 protects the PCB 20 against an outside environment and conducts electromagnetic waves generated from the various circuit components on the PCB 20 into the grounding part 60.

The electromagnetic wave conducting part 50 can comprise a pair of conductive contact parts 52 in contact with the IC 30 and the shield case 40, respectively, and an elastic part 54 accommodated between the pair of contact parts 52 to elastically keep the pair of contact parts 52 in contact with the IC 30 and the shield case 40, respectively.

The pair of contact parts 52 enhance an efficiency of shielding the electromagnetic waves by conducting the electromagnetic waves generated from the IC 30 into the shield case 40, and increasing a contact efficiency between the IC 30 and the shield case 40. Each of the pair of contact parts 52 may comprise any conductive fabric having both conductivity and flexibility. The elastic part 54 may comprise an elastic body, such as a sponge, having an elastic physical property and an economical efficiency.

Various materials may be used as the pair of contact parts 52 and the elastic part 54 as long as they can increase the electromagnetic wave shielding efficiency.

A conductive body 70 can be provided between the shield case 40 and the grounding part 60 so as to widen a ground area and enhance the contact efficiency between the shield case 40 and the grounding part 60 at the same time. The conductive body 70 may selectively employ the same structure as the electromagnetic wave conducting part 50, as well as other various structures.

When a problem such as heat generation is caused in the IC 30, a heat generating part (not shown) such as a heat sink can be attached to the IC 30 and the electromagnetic wave conducting part 50 can then be connected to the heat generating part, to thereby allow the heat generating part to contact the shield case 40 through the electromagnetic wave conducting part 50.

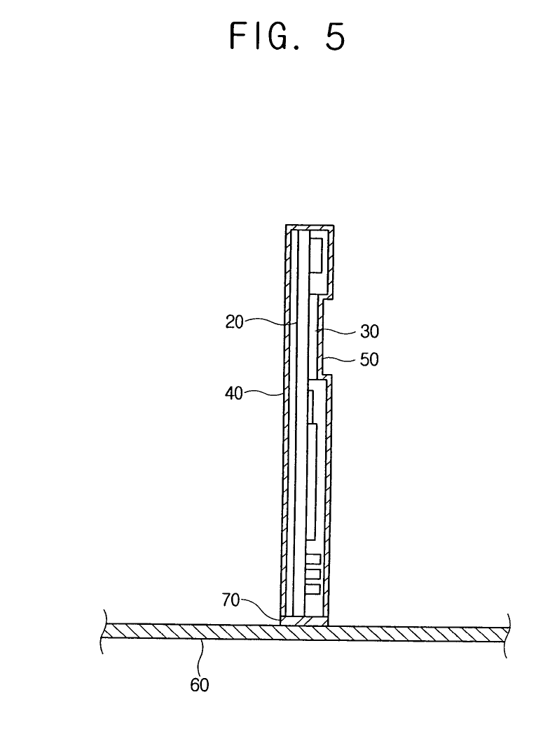

FIG. 5 is a sectional view illustrating an electromagnetic wave shielding structure of a displaying apparatus according to another embodiment of the present general inventive concept. Referring to FIG. 5, the electromagnetic wave shielding structure is substantially similar to the electromagnetic wave shielding structure of FIGS. 2 to 4, except that the electromagnetic wave conducting part 50 is projecting inward from the shield case 40 to directly contact the IC 30 on the PCB 20.

The electromagnetic wave conducting part 50 can be formed integrally or separately with the shield case 40 to improve productivity and economical efficiency.

For example, when the electromagnetic wave conducting part 50 is formed integrally with the shield case 40, it is possible that the shield case 40 and the electromagnetic wave conducting part 50 can be formed at the same time by use of a press processing.

The electromagnetic wave conducting part 50 may be modified variously, as long as the IC 30 and the shield case 40 are in contact with each other through the electromagnetic wave conducting part 50.

As described above, a displaying apparatus according to the present general inventive can prevent an EMI from being generated due to an IC mounted on a PCB, to thereby improve a functionality and a practicability of the displaying apparatus.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A displaying apparatus, comprising:
a printed circuit board (PCB);
an integrated circuit (IC) provided on the PCB;
a shield case to enclose the PCB;
an electromagnetic wave conducting part interposed between and in contact with the IC and the shield case to conduct electromagnetic waves generated from the IC into the shield case; and
a grounding part in contact with the shield case to remove the electromagnetic waves conducted into the shield case through the electromagnetic wave conducting part.

2. The displaying apparatus according to claim 1, wherein the electromagnetic wave conducting part comprises:
a pair of conductive contact parts in contact with the IC and the shield case, respectively; and
an elastic part interposed between the pair of conductive contact parts to elastically keep the pair of conductive contact parts in contact with the IC and the shield case, respectively.

3. The displaying apparatus according to claim 2, wherein each of the pair of conductive contact parts comprises a conductive fabric.

4. The displaying apparatus according to claim 1, wherein the electromagnetic wave conducting part is projecting inward from the shield case.

5. The displaying apparatus according to claim 4, wherein the electromagnetic wave conducting part is integrally formed with the shield case.

6. The displaying apparatus according to claim 1, further comprising:
a conductive body provided between the shield case and the grounding part to conduct the electromagnetic waves in the shield case into the grounding part.

7. A displaying apparatus comprising:
a shielding unit having a printed circuit board (PCB), an electrical component mounted on a surface of the PCB and generating electromagnetic waves, a shield case to enclose the PCB and the electrical component, a grounding part connected to the shield case to remove the electromagnetic waves conducted into the shield case, and a conductive part formed on the shield case to be in contact with at least one of the PCB and the electrical component.

8. The displaying apparatus according to claim 7, wherein the conductive part is disposed between the shield case and the grounding part.

9. The displaying apparatus according to claim 7, wherein the shield case comprises an opening, and the conductive part is disposed in the opening to be in contact with a portion of the PCB, the shield case, and the grounding part.

10. The displaying apparatus according to claim 7, wherein the conductive part comprises a first conductive part disposed between the shield case and the grounding part, and a second conductive part disposed between the electrical component and the shield case.

11. The displaying apparatus according to claim 7, wherein the shield case comprises a plate spaced apart from the PCB by a first distance, and the conductive part is projecting inward from the plate toward PCB and spaced apart from the surface of the PCB by a second distance.

12. The displaying apparatus according to claim 11, wherein the plate of the shield case is substantially parallel to the surface of the PCB.

13. The displaying apparatus according to claim 11, wherein the conductive part is in contact with the electrical component.

14. The displaying apparatus according to claim 11, wherein the first distance is greater than the second distance.

15. The displaying apparatus according to claim 11, wherein the electrical component has a second surface facing the plate of the shield case, and the second surface is in contact with the conductive part of the shield case.

16. The displaying apparatus according to claim 15, wherein the second surface is substantially parallel to the conductive part.

17. The displaying apparatus according to claim 7, wherein the conductive part is disposed between the shield case and the electrical component to conduct the electromagnetic waves into the shield case.

18. The displaying apparatus according to claim 17, wherein the conductive part comprises one or more conductive contact part and an elastic part.

19. The displaying case according to claim 7, wherein the conductive part is mounted on the grounding part, and the shield case is mounted on the conductive part.

20. A shielding unit usable with a displaying apparatus, comprising:
a PCB;
an electrical component mounted on a surface of the PCB and generating electromagnetic waves;
a shield case to enclose the PCB and the electrical component;
a grounding part connected to the shield case to remove the electromagnetic waves conducted into the shield case; and
a conductive part formed on the shield case to be in contact with at least one of the PCB and the electrical component.
